(19) United States
(12) Patent Application Publication
(10) Pub. No.: US 2026/0059926 A1
(43) Pub. Date: Feb. 26, 2026

(54) PHOTODETECTING DEVICE AND MANUFACTURING METHOD THEREOF

(71) Applicant: KOREA ADVANCED INSTITUTE OF SCIENCE AND TECHNOLOGY, Daejeon (KR)

(72) Inventors: Seunghyup YOO, Daejeon (KR); Sangin HAHN, Daejeon (KR); Sanghoon PARK, Daejeon (KR)

(21) Appl. No.: 19/098,112

(22) Filed: Apr. 2, 2025

(30) Foreign Application Priority Data
Aug. 21, 2024 (KR) 10-2024-0112011

(51) Int. Cl. H10K 30/20; H10K 85/20; H10K 85/60

(52) U.S. Cl. CPC H10K 30/211; H10K 85/215; H10K 85/631

(57) ABSTRACT

The present disclosure relates to a photodetecting device and a method for manufacturing the same. The photodetecting device can control the direction and magnitude of the photocurrent generated by light through the polarity and magnitude of the operating voltage, thereby exhibiting advanced photoresponsivity. Accordingly, applying the photodetecting device to various types of optical analysis systems is very advantageous in terms of complexity and operational efficiency.

### BACKGROUND OF THE INVENTION

### (a) Field of the Invention

The present disclosure relates to a photodetecting device (photodetector) and a method for manufacturing the same.

### (b) Description of the Related Art

When a photoactive layer is added to a diode, which is a rectifying element, and a reverse voltage is applied so that a small amount of reverse current basically flows, and then exposed to light, a photocurrent is generated. Conventional photodiodes are optical detection devices designed to detect the amount of light using this principle.

The photodiode changes the magnitude of the generated photocurrent depending on the wavelength and intensity of the incident light, and can be applied to various types of optical detection devices, including image sensors.

However, conventional photodiodes only generate photocurrent in the same direction as the reverse current under reverse voltage conditions, and exhibit a fixed magnitude of generated photocurrent regardless of the magnitude of the operating voltage, showing a rather simple photoresponsivity. This simple photoresponsivity greatly limits the application range of photodiodes.

### SUMMARY OF THE INVENTION

According to one embodiment of the present disclosure, a photodetecting device is provided.

According to another embodiment of the present disclosure, a method for manufacturing a photodetecting device is provided.

According to one embodiment of the present disclosure, there is provided a photodetecting device comprising a first electrode, a first charge transport layer disposed on the first electrode; a photoactive layer disposed on the first charge transport layer; a second charge transport layer disposed on the photoactive layer; and a second electrode disposed on the second charge transport layer.

The first charge transport layer, the photoactive layer, and the second charge transport layer may be semiconductor layers.

The photodetecting device may have a P-N-P structure where the first and second charge transport layers are P-type semiconductor layers, and the photoactive layer is an N-type semiconductor layer; or an N-P-N structure where the first and second charge transport layers are N-type semiconductor layers, and the photoactive layer is a P-type semiconductor layer.

The first charge transport layer, the photoactive layer, and the second charge transport layer may be formed as planar heterojunctions.

The photodetecting device may selectively transport charge through either the first or second charge transport layer depending on the polarity of the voltage applied to the first and second electrodes, causing the direction of the generated photocurrent to change.

In a photodetecting device with a P-N-P structure where the first and second charge transport layers are P-type semiconductor layers and the photoactive layer is an N-type semiconductor layer, the first and second charge transport layers may be hole transport layers.

In a photodetecting device with an N-P-N structure where the first and second charge transport layers are N-type semiconductor layers and the photoactive layer is a P-type semiconductor layer, the first and second charge transport layers may be electron transport layers. The photodetecting device may vary the magnitude of the output photocurrent depending on the magnitude of the voltage applied to the first and second electrodes.

Either one of the first electrode or the second electrode may be a transparent or semi-transparent electrode, and the other electrode may be an opaque electrode.

The semiconductor layer may be formed from one or more materials selected from the group consisting of inorganic semiconductors, organic semiconductors, perovskites, and two-dimensional semiconductors.

The N-type semiconductor layer as the photoactive layer in the P-N-P structure and the N-type semiconductor layer as the first and second charge transport layers in the N-P-N structure may each independently be formed from 1,4,5,8-naphthalene tetracarboxylic dianhydride, 3,4,9,10-perylene tetracarboxylic dianhydride, N,N′-dioctyl-3,4,9,10-naphthyl tetracarboxy diimide, oxazole derivatives (e.g., 2-(4-biphenylyl)-5-(4-t-butylphenyl)-1,3,4-oxadiazole, 2,5-di(1-naphthyl)-1,3,4-oxadiazole, etc.), triazole derivatives (e.g., 3-(4-biphenylyl)-4-phenyl-5-(4-t-butylphenyl)-1,2,4-triazole, etc.), phenanthroline derivatives, fullerene derivatives (e.g., C60 or C70, etc.), carbon nanotubes, or cyano-introduced poly-p-phenylene vinylene-based polymers (CN-PPV).

The P-type semiconductor layers as the first and second charge transport layers in the P-N-P structure and the P-type semiconductor layer as the photoactive layer in the N-P-N structure may each independently be formed from TAPC (di-[4-(N, N-di-p-tolyl-amino)-phenyl]cyclohexane), P3HT (poly-3-hexylthiophene), PBDT-TPD (Poly{4,8-bis[(2-ethylhexyl)oxy]benzo[1,2-b:4,5-b′]-dithiophene-2,6-diyl-alt-(1,3-(5-octyl-4H-thieno[3,4-c]pyrrole-4,6(5H)-dione))}), PTB7 (Poly({4,8-bis[(2-ethylhexyl)oxy]benzo[1,2-b:4,5-b′]dithiophene-2,6-diyl}{3-fluoro-2-[(2-ethylhexyl)carbonyl]thieno[3,4-b]thiophenediyl})), PBDB-T (Poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer) or PM6 (Poly[(2,6-(4,8-bis(5-(2-ethylhexyl-3-fluoro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)]).

The first and second charge transport layers and the photoactive layer may each be composed of a single layer or a multilayer of two or more layers.

A hole transport layer, an electron blocking layer, or an electron transport layer may be further interposed between the first electrode and the first charge transport layer and/or between the second electrode and the second charge transport layer.

The thickness of the photodetecting device may be 50 nm to 50 μm.

The thickness of the first charge transport layer may be 10 nm to 40 μm.

The thickness of the second charge transport layer may be 10 nm to 40 μm.

The thickness of the photoactive layer may be 10 nm to 40 μm.

Meanwhile, according to another embodiment of the present disclosure, there is provided a method for manufacturing a photodetecting device comprising the steps of forming a first electrode; disposing a first charge transport layer on the first electrode; disposing a photoactive layer on the first charge transport layer; disposing a second charge transport layer on the photoactive layer; and disposing a second electrode on the second charge transport layer.

The method may further comprise the step of disposing a hole transport layer, an electron blocking layer, or an electron transport layer on the first electrode before disposing the first charge transport layer. Meanwhile, the method may further comprise the step of disposing a hole transport layer, an electron blocking layer, or an electron transport layer on the second charge transport layer before disposing the second electrode.

The photodetecting device according to one embodiment of the present disclosure can control the direction and magnitude of the photocurrent generated by light through the polarity and magnitude of the operating voltage, thereby exhibiting advanced photoresponsivity. Accordingly, applying the photodetecting device to various types of optical analysis systems is very advantageous in terms of complexity and operational efficiency.

### BRIEF DESCRIPTION OF THE DRAWINGS

FIG. 1 is a schematic diagram showing a cross-section of a photodetecting device according to one embodiment of the present disclosure.

FIG. 2 is a diagram showing the energy level of a photodetecting device with a P-N-P structure according to one embodiment of the present disclosure.

FIG. 3 is an equivalent circuit diagram of a photodetecting device with a P-N-P structure according to one embodiment of the present disclosure.

FIG. 4 is a graph showing the photocurrent output according to the voltage when no light was irradiated (dark) or light was irradiated while adjusting the irradiance from 21 μW/cm² to 1.2 mW/cm² in a state of applying a bias voltage to the photodetecting device manufactured in Example 1.

FIG. 5 is a graph showing the current density according to the voltage when no light was irradiated (dark) or white light of AM 1.5G (100 mW/cm²) was irradiated in a state of applying a bias voltage to the photodetecting device manufactured in Comparative Example 1.

FIG. 6 is a graph showing the photocurrent output according to the irradiance at a specific voltage when the irradiance of light was adjusting from 0 mW/cm² to 1.2 mW/cm² in a state of applying a specific voltage between −1 V and 1 V to the photodetecting device manufactured in Example 1.

FIG. 7 is a graph for confirming the response speed to light of 1.2 mW/cm² when a voltage of 1 V is applied to the photodetecting device manufactured in Example 1.

FIG. 8 is a graph for confirming the response speed to light of 1.2 mW/cm² when a voltage of −1 V is applied to the photodetecting device manufactured in Example 1.

### EXPLANATION OF SYMBOLS

1A: First photodiode
1B: Second photodiode
10: First electrode
20: First charge transport layer
30: Photoactive layer
40: Second charge transport layer
50: Second electrode
I₁: Current flowing through the first photodiode (I₁=−I₂)
I₂: Current flowing through the second photodiode (I₂=−I₁)
I_{D1}: Current flowing through the diode in the equivalent circuit of the first photodiode
I_{D2}: Current flowing through the diode in the equivalent circuit of the second photodiode
I_{Ph1}: Photocurrent generated in the first photodiode
I_{Ph2}: Photocurrent generated in the second photodiode
V₁: Voltage applied to the first photodiode (V₁=V+V₂)
V₂: Voltage applied to the second photodiode (V₂=V₁−V)
R_{S1}: Series resistance of the first photodiode
R_{S2}: Series resistance of the second photodiode
R_{Sh1}: Shunt resistance of the first photodiode
R_{Sh2}: Shunt resistance of the second photodiode

### Detailed Description of the Embodiments

Hereinafter, a photodetecting device and a method for manufacturing the same according to specific embodiments of the present disclosure will be explained in detail.

According to one embodiment of the present disclosure, there is provided a photodetecting device comprising a first electrode, a first charge transport layer disposed on the first electrode; a photoactive layer disposed on the first charge transport layer; a second charge transport layer disposed on the photoactive layer; and a second electrode disposed on the second charge transport layer.

Conventional photodiodes only generate photocurrent in the same direction as the reverse current under reverse voltage conditions, and exhibit a fixed magnitude of generated photocurrent regardless of the magnitude of the operating voltage, showing a rather simple photoresponsivity. This simple photoresponsivity greatly limits the application range of photodiodes.

However, the photodetecting device of the one embodiment can control the direction and magnitude of the photocurrent through the operating voltage, thereby exhibiting advanced photoresponsivity. Accordingly, applying the photodetecting device of the one embodiment to various types of optical analysis systems can provide advantages in terms of complexity and operational efficiency.

Recently, in the case of image sensors for machine vision, image post-processing techniques using neural networks are being utilized. Applying the photodetecting device of the one embodiment to such image sensors can significantly reduce the computational load and power consumption of the system by performing post-processing at the sensor unit.

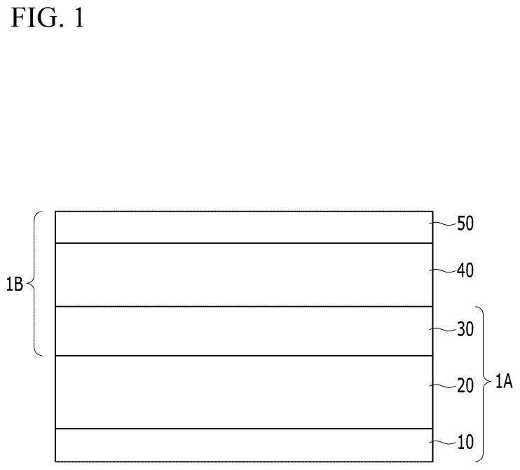

Referring to FIG. 1, the photodetecting device of the one embodiment comprises a first electrode (10), a first charge transport layer (20) disposed on the first electrode (10); a photoactive layer (30) disposed on the first charge transport layer (20); a second charge transport layer (40) disposed on the photoactive layer (30); and a second electrode (50) disposed on the second charge transport layer (40).

In the present specification, when a member is located or disposed “on” another member, it includes not only the case where the member is in contact with the other member but also the case where another member is interposed between the two members.

Referring to FIG. 1, the first electrode (10), the first charge transport layer (20), the photoactive layer (30), the second charge transport layer (40), and the second electrode (50) may be vertically stacked. This vertically stacked structure can secure a wider light-receiving area compared to photodetecting devices and systems with horizontally aligned structures such as silicon PIN diodes, resulting in a higher signal-to-noise ratio (SNR). Additionally, this vertically stacked structure can be easily integrated into the upper or lower part of other electronic devices such as thin-film transistors, providing design convenience when applied as advanced integrated devices such as image sensors.

The photodetecting device of the one embodiment may comprise the photoactive layer (30) interposed between the first charge transport layer (20) and the second charge transport layer (40).

The first charge transport layer (20), the photoactive layer (30), and the second charge transport layer (40) may be semiconductor layers. Specifically, if the first charge transport layer (20) and the second charge transport layer (40) are P-type semiconductor layers, the photoactive layer (30) may be an N-type semiconductor layer, and if the first charge transport layer (20) and the second charge transport layer (40) are N-type semiconductor layers, the photoactive layer (30) may be a P-type semiconductor layer. In the present specification, the former case may be referred to as a P-N-P structure, and the latter case may be referred to as an N-P-N structure.

The first charge transport layer (20), the photoactive layer (30), and the second charge transport layer (40) may be formed as planar heterojunctions (PHJ). Accordingly, both interfaces of the photoactive layer (30) can act as rectifiers that current selectively flow depending on the polarity (direction) of the voltage. That is, the photodetecting device of the one embodiment can exhibit bipolar photoresponsivity by having a P-N-P planar heterojunction or N-P-N planar heterojunction.

Specifically, when the photodetecting device of the one embodiment is exposed to light, excitons are generated in the photoactive layer (30) and separated into electrons and holes. One charge of the electrons and holes can flow only to one side of the first and second charge transport layers (20, 40) due to the rectifying action of both interfaces of the photoactive layer (30) and be delivered to the first or second electrode (10, 50). In other words, the photodetecting device of the one embodiment can selectively transport charge through either the first or second charge transport layer (20, 40) depending on the polarity (direction) of the voltage applied to the first and second electrodes (10, 50), causing the direction of the generated photocurrent to change, thereby exhibiting bipolar photoresponsivity.

On the other hand, when the photodetecting device of the one embodiment is not exposed to light, even if a voltage is applied to the first and second electrodes (10, 50), holes injected from the electrode to which a positive voltage is applied and electrons injected from the electrode to which a negative voltage is applied cannot pass through the first and second charge transport layers (20, 40). In other words, when a positive voltage is applied to one of the first and second electrodes (10, 50), and a negative voltage is applied to the other electrode in a state not exposed to light, holes injected from the electrode to which a positive voltage is applied and electrons injected from the electrode to which a negative voltage is applied cannot pass through the first and second charge transport layers (20, 40). Accordingly, in the absence of light, the current source values of a first photodiode (1A) and a second photodiode (1B) can be zero regardless of the polarity (direction) of the voltage. As a result, in the absence of light, no current signal may be output from the photodetecting device of the one embodiment.

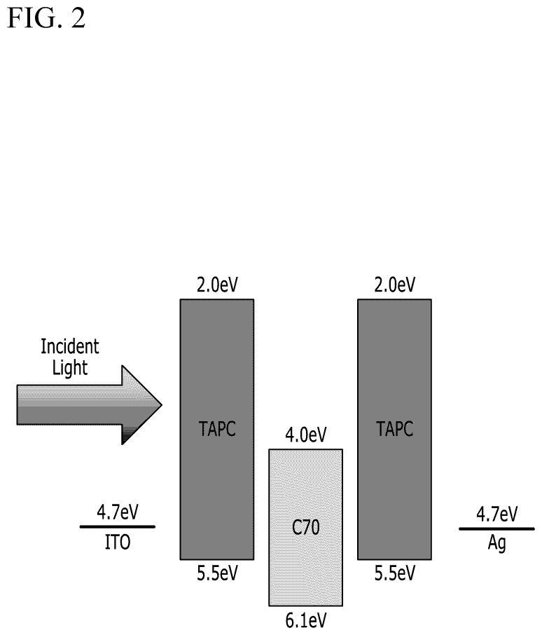

The case where the photodetecting device of the one embodiment has a P-N-P structure will be described. FIG. 2 is a diagram showing the energy level of a photodetecting device with a P-N-P structure according to one embodiment. Referring to FIG. 2, when the photodetecting device of the one embodiment has a P-N-P structure, electrons generated in the photoactive layer (30) cannot pass through the first and second charge transport layers (20, 40), and only holes can pass through. Accordingly, in the P-N-P structure, the first and second charge transport layers (20, 40) can function as hole transport layers.

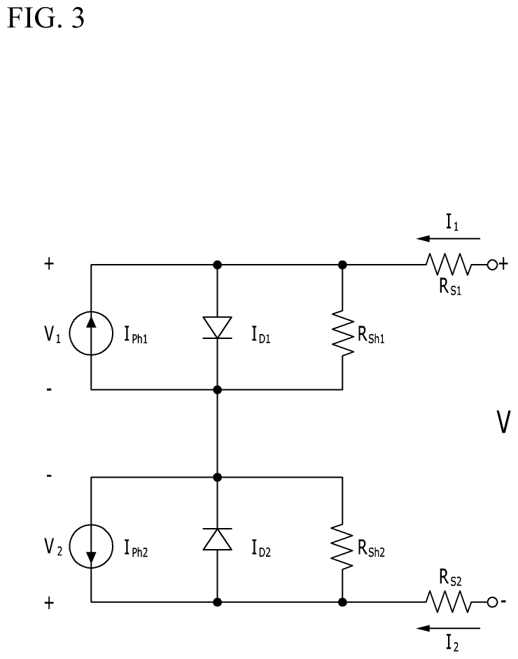

FIG. 3 is an equivalent circuit diagram of a photodetecting device with a P-N-P structure according to one embodiment. Referring to FIG. 3, the photodetecting device of the one embodiment is equivalent to two photodiodes deposited in opposite directions.

Referring to FIG. 3, when a positive voltage is applied to one of the first and second electrodes (10, 50), and a negative voltage is applied to the other electrode while exposed to light, different directions of voltage are applied to the first photodiode (1A) and the second photodiode (1B), and accordingly, only one of the charge transport layers of the first photodiode (1A) and the second photodiode (1B) (i.e., either the first charge transport layer (20) or the second charge transport layer (40)) transports charge, allowing the photocurrent to flow in only one direction. Conversely, when a negative voltage is applied to the electrode to which the positive voltage was applied, and a positive voltage is applied to the electrode to which the negative voltage was applied, the photocurrent flows in the opposite direction. In the P-N-P structure as shown in FIG. 3, the first charge transport layer (20) or the second charge transport layer (40) can transport holes to allow photocurrent to flow in any one direction.

Meanwhile, the photodetecting device of the one embodiment may have an N-P-N structure. When the photodetecting device of the one embodiment has an N-P-N structure, the first and second charge transport layers (20, 40) can function as electron transport layers.

The N-P-N structure can also output photocurrent in different directions depending on the polarity (direction) of the voltage in the same way as the P-N-P structure. In the N-P-N structure, the first charge transport layer (20) or the second charge transport layer (40) can transport electrons to allow photocurrent to flow in any one direction.

As a result, the photodetecting device of the one embodiment can exhibit bipolar photoresponsivity, with the direction of the generated photocurrent changing depending on the polarity (direction) of the voltage.

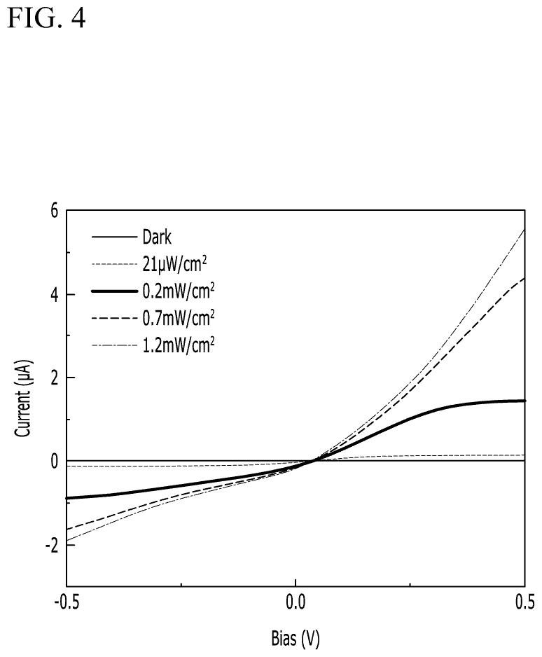

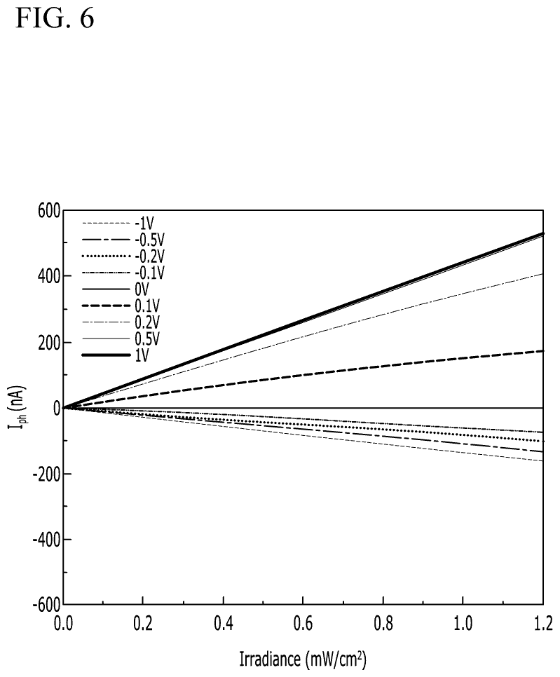

Additionally, the photodetecting device of the one embodiment can exhibit more advanced photoresponsivity by controlling the output of the photocurrent with the magnitude of the applied voltage. Specifically, referring to the test examples described later, it can be confirmed that the photodetecting device of the one embodiment increases the output of the photocurrent as the magnitude of the applied voltage increases (see FIG. 4 and FIG. 6).

At least one of the first electrode (10) and the second electrode (50) may be a transparent or semi-transparent electrode. Specifically, the transparent or semi-transparent electrode may be a film electrode made of electroconductive material such as indium tin oxide (ITO), fluorine-doped tin oxide (FTO), indium zinc oxide (IZO), or indium oxide.

The thickness of the transparent or semi-transparent electrode may be adjusted, for example, to be 5 nm or more, 10 nm or more, 30 nm or more, or 50 nm or more, and 1000 nm or less, 800 nm or less, 500 nm or less, 300 nm or less, 250 nm or less, or 200 nm or less.

The transparent or semi-transparent electrode may serve as a substrate or be formed on a separate substrate. The substrate is preferably not altered when forming the transparent or semi-transparent electrode or semiconductor layers such as the photoactive layer (30). The substrate may be made of inorganic materials such as alkali-free glass, quartz glass, or silicon, or organic materials such as polyester, polycarbonate, polyolefin, polyamide, polyimide, polyphenylene sulfide, poly-p-xylene, epoxy resin, or fluorine-based resin.

One of the first electrode (10) and the second electrode (50) may be a transparent or semi-transparent electrode, and the other electrode may be an opaque electrode. Specifically, the opaque electrode may be formed of metals such as gold (Au), silver (Ag), aluminum (Al), nickel (Ni), copper (Cu), or titanium (Ti), and in the case of manufacturing a flexible device, it may be formed of an electrically conductive polymer.

The thickness of the opaque electrode may be adjusted, for example, to be 5 nm or more, 10 nm or more, 30 nm or more, or 50 nm or more, and 1000 nm or less, 800 nm or less, 500 nm or less, 300 nm or less, 250 nm or less, or 200 nm or less.

In one example, the first electrode (10) may be a transparent or semi-transparent electrode, and the second electrode (50) may be an opaque electrode.

The semiconductor layers constituting the first and second charge transport layers (20, 40) and the photoactive layer (30) may be formed from one or more materials selected from the group consisting of inorganic semiconductors, organic semiconductors, perovskites, and two-dimensional semiconductors.

The inorganic semiconductors may be, for example, II-VI semiconductor compounds, III-V semiconductor compounds, IV-VI semiconductor compounds, Group-IV semiconductor compounds, I-III-VI semiconductor compounds, I-II-IV-VI semiconductor compounds, II-III-V semiconductor compounds, or combinations thereof. II-VI semiconductor compounds may be, for example, binary semiconductor compounds such as CdSe, CdTe, ZnS, ZnSe, ZnTe, ZnO, HgS, HgSe, HgTe, MgSe, MgS, or mixtures thereof; ternary semiconductor compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or mixtures thereof; or quaternary semiconductor compounds such as HgZnTeS, CdZnSeS, CdZnSeTe, CdZnSTe, CdHgSeS, CdHgSeTe, CdHgSTe, HgZnSeS, HgZnSeTe, HgZnSTe, or mixtures thereof, but are not limited thereto. III-V semiconductor compounds may be, for example, binary semiconductor compounds such as GaN, GaP, GaAs, GaSb, AlN, AlP, AlAs, AlSb, InN, InP, InAs, InSb, or mixtures thereof; ternary semiconductor compounds such as GaNP, GaNAs, GaNSb, GaPAs, GaPSb, AlNP, AlNAs, AlNSb, AlPAs, AlPSb, InNP, InNAs, InNSb, InPAs, InPSb, or mixtures thereof; or quaternary semiconductor compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures thereof, but are not limited thereto. IV-VI semiconductor compounds may be, for example, binary semiconductor compounds such as SnS, SnSe, SnTe, PbS, PbSe, PbTe, or mixtures thereof; ternary semiconductor compounds such as SnSeS, SnSeTe, SnSTe, PbSeS, PbSeTe, PbSTe, SnPbS, SnPbSe, SnPbTe, or mixtures thereof; or quaternary semiconductor compounds such as SnPbSSe, SnPbSeTe, SnPbSTe, or mixtures thereof, but are not limited thereto. Group-IV semiconductor compounds may be, for example, single-element semiconductor compounds such as Si, Ge, or mixtures thereof; or binary semiconductor compounds such as SiC, SiGe, or mixtures thereof, but are not limited thereto. I-III-VI semiconductor compounds may be, for example, CuInSe₂, CuInS₂, CuInGaSe, CuInGaS, or mixtures thereof, but are not limited thereto. I-II-IV-VI semiconductor compounds may be, for example, CuZnSnSe, CuZnSnS, or mixtures thereof, but are not limited thereto. II-III-V semiconductor compounds may be, for example, InZnP, but are not limited thereto.

Meanwhile, the inorganic semiconductors may be, for example, oxide semiconductors. The oxide semiconductors may be, for example, indium oxide, tin oxide, gallium oxide, zinc oxide, In-Zn oxide, Sn-Zn oxide, Al-Zn oxide, Zn-Mg oxide, Sn-Mg oxide, In-Mg oxide, In-Ga oxide, In-Ga-Zn oxide, In-Al-Zn oxide, In-Sn-Zn oxide, Sn-Ga-Zn oxide, Al-Ga-Zn oxide, Sn-Al-Zn oxide, In-Hf-Zn oxide, In-La-Zn oxide, In-Ce-Zn oxide, In-Pr-Zn oxide, In-Nd-Zn oxide, In-Sm-Zn oxide, In-Eu-Zn oxide, In-Gd-Zn oxide, In-Tb-Zn oxide, In-Dy-Zn oxide, In-Ho-Zn oxide, In-Er-Zn oxide, In-Tm-Zn oxide, In-Yb-Zn oxide, In-Lu-Zn oxide, In-Sn-Ga-Zn oxide, In-Hf-Ga-Zn oxide, In-Al-Ga-Zn oxide, In-Sn-Al-Zn oxide, In-Sn-Hf-Zn oxide, or In-Hf-Al-Zn oxide.

The organic semiconductors may be, for example, 1,4,5,8-naphthalene tetracarboxylic dianhydride, 3,4,9,10-perylene tetracarboxylic dianhydride, N,N′-dioctyl-3,4,9,10-naphthyl tetracarboxy diimide, oxazole derivatives (e.g., 2-(4-biphenylyl)-5-(4-t-butylphenyl)-1,3,4-oxadiazole, 2,5-di(1-naphthyl)-1,3,4-oxadiazole, etc.), triazole derivatives (e.g., 3-(4-biphenylyl)-4-phenyl-5-(4-t-butylphenyl)-1,2,4-triazole, etc.), phenanthroline derivatives, fullerene derivatives (e.g., C₆₀ or C₇₀, etc.), carbon nanotubes, cyano-introduced poly-p-phenylene vinylene-based polymers (CN-PPV), TAPC (di-[4-(N, N-di-p-tolyl-amino)-phenyl]cyclohexane), P3HT (poly-3-hexylthiophene), PBDT-TPD (Poly{4,8-bis[(2-ethylhexyl)oxy]benzo[1,2-b:4,5-b′]-dithiophene-2,6-diyl-alt-(1,3-(5-octyl-4H-thieno[3,4-c]pyrrole-4,6(5H)-dione))}), PTB7 (Poly({4,8-bis[(2-ethylhexyl)oxy]benzo[1,2-b: 4,5-b′]dithiophene-2,6-diyl}{3-fluoro-2-[(2-ethylhexyl)carbonyl]thieno[3,4-b]thiophenediyl})), PBDB-T (Poly[[4,8-bis[5-(2-ethylhexyl)-2- thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer) or PM6 (Poly[(2,6-(4,8-bis(5-(2-ethylhexyl-3-fluoro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)]).

The perovskites may be, for example, CH₃NH₃PbBr₃, CH₃NH₃PbI₃, CH₃NH₃SnBr₃, CH₃NH₃SnI₃, CH₃NH₃Sn₁ₓPbₓBr₃, CH₃NH₃Sn₁ₓPbₓI₃, HC(NH₂)₂PbI₃, HC(NH₂)₂SnI₃, (C₄H₉NH₃)₂PbBr₄, (C₆H₅CH₂NH₃)₂PbBr₄, (C₆H₅CH₂NH₃)₂PbI₄, (C₆H₅C₂H₄NH₃)₂PbBr₄, (C₆H₁₃NH₃)₂(CH₃NH₃)ₙ₁PbₙI₃ₙ₊₁, or combinations thereof.

The two-dimensional semiconductors may be, for example, transition metal dichalcogenides (TMD), which are compounds of transition metals and chalcogen elements, hexagonal BN (h-BN) formed by the combination of boron (B) and nitrogen (N) in a hexagonal crystal structure, phosphorene, a two-dimensional allotrope of black phosphorus, TiOₓ, NbOₓ, MnOₓ, VaOₓ, MnO₃, TaO₃, WO₃, MoCl₂, CrCl₃, RuCl₃, BiI₃, PbCl₄, GeS, GaS, GeSe, GaSe, PtSe₂, In₂Se₃, GaTe, InS, or InTe. The transition metal may be selected from the group consisting of tin (Sn), niobium (Nb), tantalum (Ta), molybdenum (Mo), tungsten (W), hafnium (Hf), titanium (Ti), and rhenium (Re), and the chalcogen element may be selected from the group consisting of sulfur (S), selenium (Se), and tellurium (Te). The transition metal dichalcogenides may be, for example, MoS₂, WS₂, TaS₂, HfS₂, ReS₂, TiS₂, NbS₂, SnS₂, MoSe₂, WSe₂, TaSe₂, HfSe₂, ReSe₂, TiSe₂, NbSe₂, SnSe₂, MoTe₂, WTe₂, TaTe₂, HfTe₂, ReTe₂, TiTe₂, NbTe₂ or SnTe_{2.}

In one example, the semiconductor layers constituting the first and second charge transport layers (20, 40) and the photoactive layer (30) may be formed from organic semiconductors. The organic semiconductors have the advantage of easy molecular structure design and layer thickness control, and are advantageous for large-area device fabrication through deposition or solution coating processes.

The N-type semiconductor layer as the photoactive layer (30) in the P-N-P structure, and the N-type semiconductor layer as the first and second charge transport layers (20, 40) in the N-P-N structure may be formed from, for example, 1,4,5,8-naphthalene tetracarboxylic dianhydride, 3,4,9,10-perylene tetracarboxylic dianhydride, N,N′-dioctyl-3,4,9,10-naphthyl tetracarboxy diimide, oxazole derivatives (e.g., 2-(4-biphenylyl)-5-(4-t-butylphenyl)-1,3,4-oxadiazole, 2,5-di(1-naphthyl)-1,3,4-oxadiazole, etc.), triazole derivatives (e.g., 3-(4-biphenylyl)-4-phenyl-5-(4-t-butylphenyl)-1,2,4-triazole, etc.), phenanthroline derivatives, fullerene derivatives (e.g., C₆₀ or C₇₀, etc.), carbon nanotubes, or cyano-introduced poly-p-phenylene vinylene-based polymers (CN-PPV).

The P-type semiconductor layers as the first and second charge transport layers (20, 40) in the P-N-P structure, and the P-type semiconductor layer as the photoactive layer (30) in the N-P-N structure may be formed from, for example, TAPC (di-[4-(N, N-di-p-tolyl-amino)-phenyl]cyclohexane), P3HT (poly-3-hexylthiophene), PBDT-TPD (Poly{4,8-bis[(2-ethylhexyl)oxy]benzo[1,2-b:4,5-b′]-dithiophene-2,6-diyl-alt-(1,3-(5-octyl-4H-thieno[3,4-c]pyrrole-4,6(5H)-dione))}), PTB7 (Poly({4,8-bis[(2-ethylhexyl)oxy]benzo[1,2-b: 4,5-b′]dithiophene-2,6-diyl}{3-fluoro-2-[(2-ethylhexyl)carbonyl]thieno[3,4-b]thiophenediyl})), PBDB-T (Poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer) or PM6 (Poly[(2,6-(4,8-bis(5-(2-ethylhexyl-3-fluoro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)]).

The first and second charge transport layers (20, 40) and the photoactive layer (30) may each be composed of a single layer or a multilayer of two or more layers.

The photodetecting device of the one embodiment may further comprise any layer such as a hole transport layer, an electron blocking layer, or an electron transport layer interposed between the first electrode (10) and the first charge transport layer (20) and/or between the second electrode (50) and the second charge transport layer (40). As a non-limiting example, a hole transport layer such as molybdenum oxide (MoOₓ) may be further interposed between the first electrode (10) and the first charge transport layer (20) and between the second electrode (50) and the second charge transport layer (40).

The photodetecting device of the one embodiment has a thin-film structure, allowing the response characteristics to be adjusted through the optical design of the device itself, and due to its thin thickness, it is easy to manufacture ultra-thin and flexible devices, which can be applied to various types of platforms.

Specifically, the total thickness of the photodetecting device may be adjusted, for example, to be 50 nm or more, 100 nm or more, 300 nm or more, or 400 nm or more, and 50 μm or less, 30 μm or less, 10 μm or less, 5 μm or less, 1 μm or less, 800 nm or less, or 600 nm or less.

The thickness of the first charge transport layer (20) may be adjusted, for example, to be 10 nm or more, 20 nm or more, 30 nm or more, 40 nm or more, 50 nm or more, or 60 nm or more, and 40 μm or less, 10 μm or less, 1 μm or less, 500 nm or less, 300 nm or less, 200 nm or less, or 150 nm or less. If the first charge transport layer (20) is a multilayer structure of two or more layers, the thickness of the first charge transport layer (20) refers to the total thickness of the multilayer structure.

The thickness of the second charge transport layer (40) may be adjusted, for example, to be 10 nm or more, 20 nm or more, 30 nm or more, 40 nm or more, 50 nm or more, or 60 nm or more, and 40 μm or less, 10 μm or less, 1 μm or less, 500 nm or less, 300 nm or less, 200 nm or less, or 150 nm or less. If the second charge transport layer (40) is a multilayer structure of two or more layers, the thickness of the second charge transport layer (40) refers to the total thickness of the multilayer structure.

The thickness of the photoactive layer (30) may be adjusted, for example, to be 10 nm or more, 20 nm or more, 30 nm or more, 40 nm or more, 50 nm or more, or 60 nm or more, and 40μm or less, 10 μm or less, 1 μm or less, 500 nm or less, 300 nm or less, 200 nm or less, or 150 nm or less. If the photoactive layer (30) is a multilayer structure of two or more layers, the thickness of the photoactive layer (30) refers to the total thickness of the multilayer structure.

Meanwhile, according to another embodiment of the invention, there is provided a method for manufacturing a photodetecting device comprising the steps of forming a first electrode (10); disposing a first charge transport layer (20) on the first electrode (10); disposing a photoactive layer (30) on the first charge transport layer (20); disposing a second charge transport layer (40) on the photoactive layer (30); and disposing a second electrode (50) on the second charge transport layer (40).

Since the first and second electrodes (10, 50), the first and second charge transport layers (20, 40), and the photoactive layer (30) have been described in detail earlier, detailed descriptions are omitted here.

At least one of the first and second electrodes (10, 50) may be a transparent or semi-transparent electrode. The transparent or semi-transparent electrode can be formed by vacuum deposition. Meanwhile, one of the other of the first and second electrodes (10, 50) may be an opaque electrode. The opaque electrode can be formed by vacuum deposition, sputtering, ion plating, or plating.

The first and second charge transport layers (20, 40) and the photoactive layer (30) may be semiconductor layers. Accordingly, in the steps of disposing the first charge transport layer (20), disposing the photoactive layer (30), and disposing the second charge transport layer (40), the respective layers can be formed (disposed) using appropriate semiconductor materials. As a non-limiting example, if the semiconductor layer is formed from inorganic materials, it can be formed by methods such as vacuum deposition, sputtering, or ion plating, and if formed from organic materials, it can be formed by methods such as thermal deposition or spin coating.

The photodetecting device manufactured by method according to another embodiment may further comprise any layer such as a hole transport layer, an electron blocking layer, or an electron transport layer interposed between the first electrode (10) and the first charge transport layer (20) and/or between the second electrode (50) and the second charge transport layer (40). Accordingly, the method according to another embodiment may comprise the step of further disposing any layer such as a hole transport layer, an electron blocking layer, or an electron transport layer on the first electrode (10) before disposing the first charge transport layer (20), or the step of further disposing a hole transport layer, an electron blocking layer, or an electron transport layer on the second charge transport layer (40) before disposing the second electrode (50).

Hereinafter, the actions and effects of the invention will be explained in detail through specific examples. However, these examples are presented only as the illustrations of the invention, and the scope of the right of the invention is not limited thereby.

### Example 1: Preparation of Photodetecting Device (Bipolar Photodetecting Device)

Indium tin oxide (ITO) was vacuum deposited to a thickness of 150 nm on a glass substrate to form a first electrode. TAPC (di-[4-(N, N-di-p-tolylamino)phenyl]cyclohexane) was thermally deposited to a thickness of 80 nm to form a first charge transport layer on the first electrode. C₇₀ was thermally deposited to a thickness of 69 nm to form a photoactive layer on the first charge transport layer. TAPC (di-[4-(N, N-di-p-tolylamino)phenyl]cyclohexane) was thermally deposited to a thickness of 80 nm to form a second charge transport layer on the photoactive layer. Silver (Ag) was deposited to a thickness of 100 nm in a metal deposition chamber to form a second electrode on the second charge transport layer, thereby manufacturing a photodetecting device with the structure shown in FIG. 1.

The photodetecting device has a P-N-P structure where the first and second charge transport layers are P-type semiconductor layers, and the photoactive layer is an N-type semiconductor layer, showing the energy level as shown in FIG. 2.

### Comparative Example 1: Preparation of Photodetecting device (Conventional Photodiode)

Indium tin oxide (ITO) was vacuum deposited to a thickness of 150 nm on a glass substrate to form a transparent electrode. ZnO was deposited to a thickness of 40 nm as an electron transport layer on the transparent electrode, PM6: Y7 was deposited to a thickness of 130 nm as a photoactive layer, TAPC was deposited to a thickness of 10 nm as a hole transport layer, and molybdenum oxide was deposited to a thickness of 10 nm, followed by the deposition of silver (Ag) to a thickness of 100 nm to manufacture a conventional photodiode.

### Test Example: Performance Evaluation of Photodetecting Device

### (1) Evaluation of Voltage-Current Characteristics of Photodetecting Device

FIG. 4 is a graph showing the photocurrent output according to the voltage when no light was irradiated (dark) or light was irradiated while adjusting the irradiance from 21 μW/cm² to 1.2 mW/cm² in a state of applying a bias voltage to the photodetecting device manufactured in Example 1.

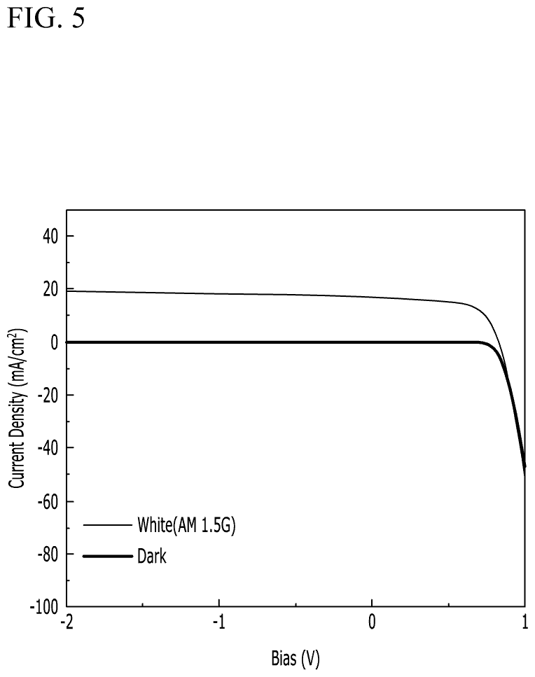

FIG. 5 is a graph showing the current density according to the voltage when no light was irradiated (dark) or white light of AM 1.5 G (100 mW/cm²) was irradiated in a state of applying a bias voltage to the photodetecting device manufactured in Comparative Example 1.

Referring to FIG. 4, it can be confirmed that the photodetecting device manufactured in Example 1 outputs photocurrent in different directions when voltages with different polarities (directions) are applied in the presence of light. Additionally, it can be confirmed that the photodetecting device manufactured in Example 1 shows increased photocurrent output as the magnitude of the voltage increases and the irradiance increases.

However, referring to FIG. 5, it can be confirmed that the photodetecting device (conventional photodiode) manufactured in Comparative Example 1 shows a constant current density only when a voltage is applied in one direction, regardless of the magnitude of the voltage. Thus, it is confirmed that the photodetecting device of the one embodiment is capable of bipolar response, and the output of the photocurrent varies depending on the magnitude of the applied voltage and the intensity of the incident light.

### (2) Evaluation of Photoresponsivity of Photodetecting Device

FIG. 6 is a graph showing the photocurrent output according to the irradiance at a specific voltage when the irradiance of light was adjusting from 0 mW/cm² to 1.2 mW/cm² in a state of applying a specific voltage between −1 V and 1 V to the photodetecting device manufactured in Example 1.

Referring to FIG. 6, it can be confirmed that the photodetecting device manufactured in Example 1 can control not only the direction but also the magnitude of the photocurrent by adjusting the operating voltage, and the photocurrent output increases linearly as the irradiance increases at voltages between −1 V and 1 V.

Thus, it is confirmed that the photodetecting device of the one embodiment can control the direction and magnitude, and particularly exhibits linear photoresponsivity with respect to the irradiance.

### (3) Evaluation of Response Speed of Photodetecting Device

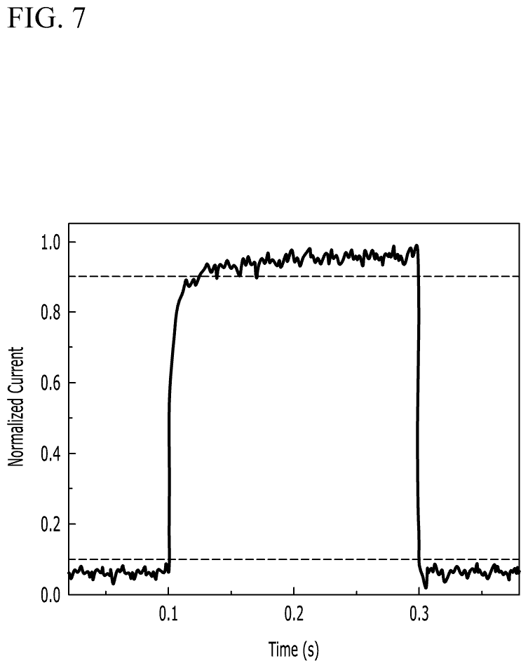

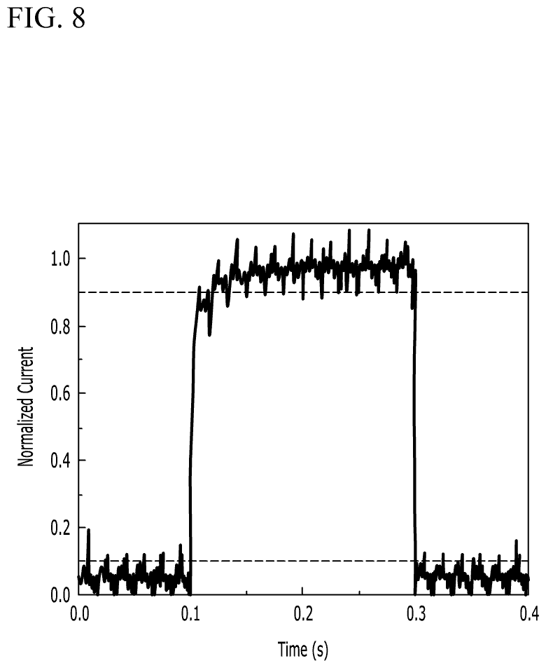

FIG. 7 is a graph for confirming the response speed to light of 1.2 mW/cm² when a voltage of 1 V is applied to the photodetecting device manufactured in Example 1, and FIG. 8 is a graph for confirming the response speed to light of 1.2 mW/cm² when a voltage of −1 V is applied to the photodetecting device manufactured in Example 1.

Referring to FIG. 7, the rise time under the condition of an irradiance of 1.2 mW/cm² and a voltage of 1 V was 23.1 ms, and the fall time was 0.3 ms. Referring to FIG. 8, the rise time under the condition of an irradiance of 1.2 mW/cm² and a voltage of −1 V was 18.1 ms, and the fall time was 0.4 ms.

Thus, it is confirmed that the photodetecting device of the one embodiment exhibits fast response speeds when voltages are applied in both directions.

What is claimed is:

1. A photodetecting device comprising a first electrode, a first charge transport layer disposed on the first electrode; a photoactive layer disposed on the first charge transport layer; a second charge transport layer disposed on the photoactive layer; and a second electrode disposed on the second charge transport layer.

2. The photodetecting device according to claim 1, wherein the first charge transport layer, the photoactive layer, and the second charge transport layer are semiconductor layers.

3. The photodetecting device according to claim 1, wherein the first and second charge transport layers are P-type semiconductor layers, and the photoactive layer is an N-type semiconductor layer in a P-N-P structure; or the first and second charge transport layers are N-type semiconductor layers, and the photoactive layer is a P-type semiconductor layer in an N-P-N structure.

4. The photodetecting device according to claim 1, wherein the first charge transport layer, the photoactive layer, and the second charge transport layer are formed as planar heterojunctions.

5. The photodetecting device according to claim 1, wherein the direction of the generated photocurrent changes by selectively transporting charge through either the first or second charge transport layer depending on the polarity of the voltage applied to the first and second electrodes.

6. The photodetecting device according to claim 1, wherein the first and second charge transport layers are P-type semiconductor layers, the photoactive layer is an N-type semiconductor layer in a P-N-P structure, and the first and second charge transport layers are hole transport layers.

7. The photodetecting device according to claim 1, wherein the first and second charge transport layers are N-type semiconductor layers, the photoactive layer is a P-type semiconductor layer in an N-P-N structure, and the first and second charge transport layers are electron transport layers.

8. The photodetecting device according to claim 1, wherein the magnitude of the output photocurrent varies depending on the magnitude of the voltage applied to the first and second electrodes.

9. The photodetecting device according to claim 1, wherein either one of the first electrode or the second electrode is a transparent or semi-transparent electrode, and the other electrode is an opaque electrode.

10. The photodetecting device according to claim 2, wherein the semiconductor layer is formed from one or more materials selected from the group consisting of inorganic semiconductors, organic semiconductors, perovskites, and two-dimensional semiconductors.

11. The photodetecting device according to claim 3, wherein the N-type semiconductor layer as the photoactive layer in the P-N-P structure and the N-type semiconductor layer as the first and second charge transport layers in the N-P-N structure are each independently formed from 1,4,5,8-naphthalene tetracarboxylic dianhydride, 3,4,9,10-perylene tetracarboxylic dianhydride, N,N′-dioctyl-3,4,9,10-naphthyl tetracarboxy diimide, oxazole derivatives, triazole derivatives, phenanthroline derivatives, fullerene derivatives, carbon nanotubes, or cyano-introduced poly-p-phenylene vinylene-based polymers (CN-PPV).

12. The photodetecting device according to claim 3, wherein the P-type semiconductor layers as the first and second charge transport layers in the P-N-P structure and the P-type semiconductor layer as the photoactive layer in the N-P-N structure are each independently formed from TAPC (di-[4-(N, N-di-p-tolyl-amino)-phenyl]cyclohexane), P3HT (poly-3-hexylthiophene), PBDT-TPD (Poly{4,8-bis[(2-ethylhexyl)oxy]benzo[1,2-b:4,5-b′]-dithiophene-2,6-diyl-alt-(1,3-(5-octyl-4H-thieno[3,4-c]pyrrole-4,6(5H)-dione))}), PTB7 (Poly({4,8-bis[(2-ethylhexyl)oxy]benzo[1,2-b: 4,5-b′]dithiophene-2,6-diyl}{3-fluoro-2-[(2-ethylhexyl)carbonyl]thieno[3,4-b]thiophenediyl})), PBDB-T (Poly[[4,8-bis[5-(2-ethylhexyl)-2- thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer) or PM6 (Poly[(2,6-(4,8-bis(5-(2-ethylhexyl-3-fluoro)thiophen-2-yl)-benzo[1,2-b: 4,5-b′]dithiophene))-alt-(5,5-(1′,3′-di-2-thienyl-5′,7′-bis(2-ethylhexyl)benzo[1′,2′-c:4′,5′-c′]dithiophene-4,8- dione)]).

13. The photodetecting device according to claim 1, wherein the first and second charge transport layers and the photoactive layer are each composed of a single layer or a multilayer of two or more layers.

14. The photodetecting device according to claim 1, wherein a hole transport layer, an electron blocking layer, or an electron transport layer is further interposed between the first electrode and the first charge transport layer and/or between the second electrode and the second charge transport layer.

15. The photodetecting device according to claim 1, wherein the thickness of the photodetecting device is 50 nm to 50 μm.

16. The photodetecting device according to claim 1, wherein the thickness of the first charge transport layer is 10 nm to 40μm.

17. The photodetecting device according to claim 1, wherein the thickness of the second charge transport layer is 10 nm to 40μm.

18. The photodetecting device according to claim 1, wherein the thickness of the photoactive layer is 10 nm to 40μm.

19. A method for manufacturing a photodetecting device comprising the steps of forming a first electrode; disposing a first charge transport layer on the first electrode; disposing a photoactive layer on the first charge transport layer; disposing a second charge transport layer on the photoactive layer; and disposing a second electrode on the second charge transport layer.

20. The method for manufacturing a photodetecting device according to claim 19, further comprising the step of disposing a hole transport layer, an electron blocking layer, or an electron transport layer on the first electrode before disposing the first charge transport layer; or
the step of disposing a hole transport layer, an electron blocking layer, or an electron transport layer on the second charge transport layer before disposing the second electrode.
